(19) United States
(12) Patent Application Publication
(10) Pub. No.: US 2026/0037479 A1
(43) Pub. Date: Feb. 5, 2026

(54) IN-MEMORY COMPUTING ACCELERATOR USING HIGH-DENSITY OPERATION CIRCUIT AND LOW-POWER SENSE AMPLIFIER AS PERIPHERAL CIRCUIT

(71) Applicant: Korea Advanced Institute of Science and Technology, Daejeon (KR)

(72) Inventors: Hoi Jun YOO, Daejeon (KR); Seong Yon HONG, Daejeon (KR)

(73) Assignee: Korea Advanced Institute of Science and Technology, Daejeon (KR)

(21) Appl. No.: 19/004,486

(22) Filed: Dec. 30, 2024

(30) Foreign Application Priority Data
Jul. 30, 2024 (KR) 10-2024-0100629

(51) Int. Cl. G06F 15/80; G11C 11/4091

(52) U.S. Cl. CPC G06F 15/8023; G11C 11/4091

(57) ABSTRACT

An in-memory computing (IMC) accelerator using a high-density operation circuit and a low-power sense amplifier as a peripheral circuit includes a plurality of dynamic random-access memory (DRAM) banks each including a pair of cell arrays, a data supply logic, a memory, and a controller for IMC, a global SRAM, and a top-level controller, wherein the cell array includes a plurality of subarrays, each of the subarrays includes a DRAM array including a big array and a little array, and an arithmetic circuit configured to perform an operation, and the arithmetic circuit includes a sense amplifier configured to amplify a bit line voltage difference, and a compact multiply-accumulate (MAC)-single instruction multiple data (SIMD) unit (CMSU) for an MAC operation and an SIMD operation, so that functionality of an in-memory operation is diversified.

### CROSS-REFERENCE TO RELATED APPLICATION

This application claims the benefit of priority under 35 U.S.C. § 119(a) to Korean Patent Application No. 10-2024-0100629, filed on Jul. 30, 2024, the entire contents of which are incorporated herein by reference.

### BACKGROUND OF THE INVENTION

### Field of the Invention

The present invention relates to an in-memory computing (IMC) accelerator using a high-density operation circuit and a low-power sense amplifier as a peripheral circuit, and more particularly to an IMC accelerator using a high-density operation circuit and a low-power sense amplifier as a peripheral circuit configured to perform energy-efficient and high-accuracy analog multiply-accumulate (MAC) operation and digital single instruction multiple data (SIMD) operation on a high-density arithmetic circuit including 8T1C.

In addition, the present invention relates to an IMC accelerator using a high-density operation circuit and a low-power sense amplifier as a peripheral circuit, and more particularly to an IMC accelerator using a dual mode sense amplifier selectable between a differential sense mode and a direct sense mode, a high-density operation circuit having a high retention time while performing a memory read operation through a big-little memory array at low power, and a low-power sense amplifier as a peripheral circuit.

### Description of the Related Art

Dynamic random-access memory (DRAM) IMC has high memory density and reduces external memory access, thereby increasing energy efficiency of an artificial intelligence (AI) acceleration system.

This offers great advantages, especially in modern computing environments that perform data-intensive tasks. However, current DRAM IMC technology faces four major challenges.

First, memory density is low even though a DRAM cell is used. The operation cell area of the existing DRAM IMC accelerator is 13 times the area of a DRAM cell used as a memory and 36 times the area of an SRAM cell. A reason therefor is that two or more transistors or two or more capacitors are integrated per cell for in-memory operation. An IMC accelerator using a 1T1C cell has a problem of not being able to utilize high-density characteristics of a DRAM since half of a cell array is removed to integrate operators.

Second, a lot of energy is consumed in a data read operation for operation. In particular, in the case of a technology that reads data using a sense amplifier of a DRAM and then performs an operation in a peripheral circuit or an operator outside a memory array, consumed memory access energy is greater than or equal to operation energy due to driving of the sense amplifier and a change in bit line (BL) voltage for the read operation. This has a problem of limiting operation energy efficiency of a system including memory access.

Third, a bit-serial bit-parallel (BPBS) data flow used in conventional analog IMC technology has limitations in achieving high energy efficiency while maintaining accuracy of the latest AI models. The BPBS data flow is a scheme in which weight data of an AI model is stored in an operation cell array and computed in a bit parallel manner and input data is applied through an operation word line and computed in a bit serial manner. This scheme has a problem of limiting energy efficiency by repeatedly requiring analog-to-digital converter (ADC) operation and digital accumulation for each single input bit.

Fourth, even though the latest AI models require various types of operations, only MAC operations are supported by IMC and functionality is limited. In particular, in the case of a technology of operation in a memory cell, in-memory operation using this is limited in terms of functionality in supporting functionality limited to bit-wise AND logic operations.

In addition to MAC operations, it is necessary to support logical and arithmetic operations for AI models such as biased addition, softmax operation, and activation function operation.

These problems limit performance of DRAM-based IMC technology, suggesting the need for a new approach to overcome this limitation. The present invention has been devised to solve these problems, and presents an invention that may simultaneously improve memory density and operation energy efficiency.
(Non-Patent Document 0001) [1] Kwon, Young-Cheon, et al “A 20 nm 6 GB Function-In-Memory DRAM, Based on HBM2 with a 1.2TFLOPS Programmable Computing Unit Using Bank-Level Parallelism, for Machine Learning Applications” 2021 IEEE International Solid-State Circuits Conference (ISSCC) Vol 64 IEEE, 2021
(Non-Patent Document 0002) [2] Lee, Seongju, et al “A 1ynm 1.25V 8 Gb 16 Gb/s/Pin GDDR6-Based Accelerator-in-Memory Supporting 1TFLOPS MAC Operation and Various Activation Functions for Deep Learning Application” 2022 IEEE International Solid-State Circuits Conference (ISSCC) Vol 65 IEEE, 2022
(Non-Patent Document 0003) [3] Xie, Shanshan, et al “eDRAM-CIM: Compute-In-Memory Design with Reconfigurable Embedded Dynamic Memory Array Realizing Adaptive Data Converters and Charge Domain Computing” 2021 IEEE International Solid-State Circuits Conference (ISSCC) Vol 64 IEEE, 2021
(Non-Patent Document 0004) [4] Chen, Zhengyu, Xi Chen, and Jie Gu “A 65 nm 3T Dynamic Analog RAM-Based Computing-in-Memory Macro and CNN Accelerator with Retention Enhancement, Adaptive Analog Sparsity and 44TOPS/W System Energy Efficiency” 2021 IEEE International Solid-State Circuits Conference (ISSCC) Vol 64 IEEE, 2021
(Non-Patent Document 0005) [5] Xie, Shanshan, et al “Gain-Cell CIM: Leakage and Bitline Swing Aware 2T1C Gain-Cell eDRAM Compute in Memory Design with Bitline Precharge DACs and Compact Schmitt Trigger ADCs” 2022 IEEE Symposium on VLSI Technology and Circuits (VLSI Technology and Circuits) IEEE, 2022
(Non-Patent Document 0006) [6] Kim, Sangjin, et al “165 DynaPlasia: An e DRAM In-Memory-Computing-Based Reconfigurable Spatial Accelerator with Triple-Mode Cell for Dynamic Resource Switching” 2023 IEEE International Solid-State Circuits Conference (ISSCC) IEEE, 2023
(Non-Patent Document 0007) [7] Kim, Sangiin, et al “Scaling-CIM: An eDRAM-based 5 In-Memory-Computing Accelerator with Dynamic-Scaling ADC for SQNR-Boosting and Layer-wise Adaptive Bit-Truncation” 2023 IEEE Symposium on VLSI Technology and Circuits (VLSI Technology and Circuits) IEEE, 2023

### SUMMARY OF THE INVENTION

To solve the above-mentioned problems and meet the needs, an object of an IMC accelerator using a high-density operation circuit and a low-power sense amplifier as a peripheral circuit according to the present invention is to improve memory density of a DRAM IMC accelerator by utilizing a high-density memory cell having a 1T1C structure and a high-density operation circuit having an 8T1C structure to minimize the area of an additional transistor and capacitor required for an in-memory operation.

In addition, to solve the above-mentioned problems and satisfy the needs, an object of an IMC accelerator using a high-density operation circuit and a low-power sense amplifier as a peripheral circuit according to the present invention is to maintain a high retention time while reducing energy consumption of a data read operation of a DRAM IMC accelerator using a dual mode sense amplifier having a differential sense mode and a direct sense mode and a big-little memory array structure in which a memory array is divided into a big array and a little array.

In addition, to solve the above-mentioned problems and meet the needs, an object of an IMC accelerator using a high-density operation circuit and a low-power sense amplifier as a peripheral circuit according to the present invention is to improve energy efficiency of an IMC accelerator by introducing a column addition data flow and analog column addition operation to maximize accumulation of partial sums of output data in terms of analog voltage while minimizing ADC operation.

In addition, to solve the above-mentioned problems and meet the needs, an object of an IMC accelerator using a high-density operation circuit and a low-power sense amplifier as a peripheral circuit according to the present invention is to improve a signal-to-quantization-noise ratio (SQNR) of an IMC accelerator by increasing signal strength of an operation corresponding to a high-bit position of output data through a signal enhancement operation capacitor array.

In addition, to solve the above-mentioned problems and meet the needs, an object of an IMC accelerator using a high-density operation circuit and a low-power sense amplifier as a peripheral circuit according to the present invention is to expand functionality of an IMC accelerator by supporting 16 logical SIMD operations and various arithmetic SIMD operations using an in-memory SIMD operation utilizing the 8T1C high-density operation circuit and the dual mode sense amplifier.

In accordance with an aspect of the present invention, the above and other objects can be accomplished by the provision of an in-memory computing (IMC) accelerator using a high-density operation circuit and a low-power sense amplifier as a peripheral circuit, the IMC accelerator including a plurality of dynamic random-access memory (DRAM) banks each including a pair of cell arrays, a data supply logic, a memory, and a controller for IMC, and including a DRAM having a predetermined capacity to store data as a memory or perform an in-memory operation, a global SRAM configured to temporarily store data when exchanging data with an off-chip memory, and a top-level controller configured to adjust data movement between the off-chip memory and the DRAM bank, or between different DRAM banks, decode an operation instruction, and transmit the decoded operation instruction to each DRAM bank, wherein the cell array includes a plurality of subarrays, each of the subarrays includes a DRAM array including a big array and a little array, and an arithmetic circuit configured to perform an operation, and the arithmetic circuit includes a sense amplifier configured to amplify a bit line voltage difference, and a compact multiply-accumulate (MAC)-single instruction multiple data (SIMD) unit (CMSU) for an MAC operation and an SIMD operation.

The arithmetic circuit may have an 8T1C circuit structure having a multiplexer to which a transistor and an operation capacitor are connected to select an input operand, perform a logical operation on an operand, select whether to store output, and select an MAC operation or an analog-to-digital converter (ADC) operation.

The capacitor may perform both a MAC operation of a capacitance-coupled scheme and a DAC operation of a successive approximation register (SAR) ADC.

The multiplexer may select one operand from among input outside a memory array or output of an adjacent arithmetic circuit to select the input operand.

For a logical operation on the operand, the multiplexer may receive a selection signal from a bit line and a bit line bar to use the selection signal as an operand A, and receive two input signals as one of bits of an operand B, inverted bits of the operand B, GND, and VDD to perform 16 types of logical operations between the operands A and B.

The multiplexer may store output bits of the multiplexer for the logical operation on the operand in the capacitor to select whether to store the output, then share a charge on the bit line, and operate the sense amplifier to perform a memory write operation.

The sense amplifier may include an N-MOSFET and a P-MOSFET for voltage difference amplification of a bit line and a bit line bar, and an additional N-MOSFET and an additional P-MOSFET for selection of the bit line or the bit line bar.

The sense amplifier may be reconfigurable to selectively operate in either a differential sense mode or a direct sense mode.

In the differential sense mode, two N-MOSFETs and two P-MOSFETs for selecting the bit line or the bit line bar of the sense amplifier may be both turned on to amplify the bit line voltage difference.

In the direct sense mode, when data of a cell connected to the bit line or the bit line bar is read, one N-MOSFET and one P-MOSFET for selection of the bit line or the bit line bar may be exclusively turned on, so that a voltage difference is amplified based on whether a voltage of the bit line or the bit line bar exceeds a threshold voltage of the N-MOSFET for amplification of the voltage difference.

The DRAM array may include a big array including 64 memory rows, a little array including 8 memory rows, and a bit line switch configured to separate the big array and the little array.

The MAC operation may have a column addition data flow configured to sequentially accumulate MAC operation results of input data and weight data from a least significant bit (LSB) position to a most significant bit (MSB) position.

The column addition data flow may be allowed to perform an analog column addition operation using a capacitor coupling scheme and a signal weakening scheme in an analog voltage domain.

The MAC operation may have, as a differential capacitor array structure having a pair of operation lines (CL+ and CL−), a separated capacitor array structure in which each operation line is separated into CL0+ and CL0− to which one quarter of entire capacitors are connected, CL1+ and CL1− to which one quarter of the entire capacitors are connected, and CL2+ and CL2− to which half of the entire capacitors are connected.

The SIMD operation may perform an arithmetic operation by combining repeated logical operations between two operands among input data outside a memory array, data read from the memory array, and output data of an adjacent arithmetic circuit.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a diagram illustrating the need and overview of a 1T1C DRAM IMC accelerator using an area-efficient arithmetic circuit and a low-power sense amplifier as a peripheral circuit according to the present invention;

FIG. 2 is a diagram illustrating an overall architecture of the 1T1C DRAM IMC accelerator according to the present invention;

FIG. 3 is a diagram illustrating a structure of an 8T1C high-density operation circuit and operations of a MAC and an SIMD according to the present invention;

FIG. 4A is a diagram illustrating a structure of a big-little memory array and operations in a differential sense mode and a direct sense mode in a dual mode sense amplifier according to the present invention;

FIG. 4B is a diagram illustrating read operation waveforms in the differential sense mode and the direct sense mode of the dual mode sense amplifier according to the present invention;

FIG. 5A is a diagram illustrating structures of an input column shifter, an input phase inverter, and an output voltage attenuator for supporting a column addition data flow according to the present invention;

FIG. 5B is a diagram illustrating an operation of an analog column addition operation according to the present invention as a formula and a waveform;

FIG. 6 is a diagram illustrating a structure and an operation of a signal enhancement operation capacitor array according to the present invention; and

FIG. 7 is a diagram illustrating a type and method of in-memory SIMD operation according to the present invention.

### DETAILED DESCRIPTION OF THE INVENTION

Terms or words used in this specification and claims should not be interpreted as limited to usual or dictionary meanings, but should be interpreted as having meanings and concepts that conform to the technical idea of the present invention, based on the principle that the inventor may appropriately define the concept of a term to best describe the invention.

Therefore, the embodiments described in this specification and the configurations illustrated in the drawings are only the most preferred embodiments of the present invention and do not represent all of the technical ideas of the present invention. Therefore, it should be understood that there may be various equivalents and modified examples that may replace the embodiments at the time of filing this application.

Hereinafter, a detailed description will be given of an IMC accelerator using a high-density operation circuit and a low-power sense amplifier as a peripheral circuit according to the present invention with reference to the attached drawings.

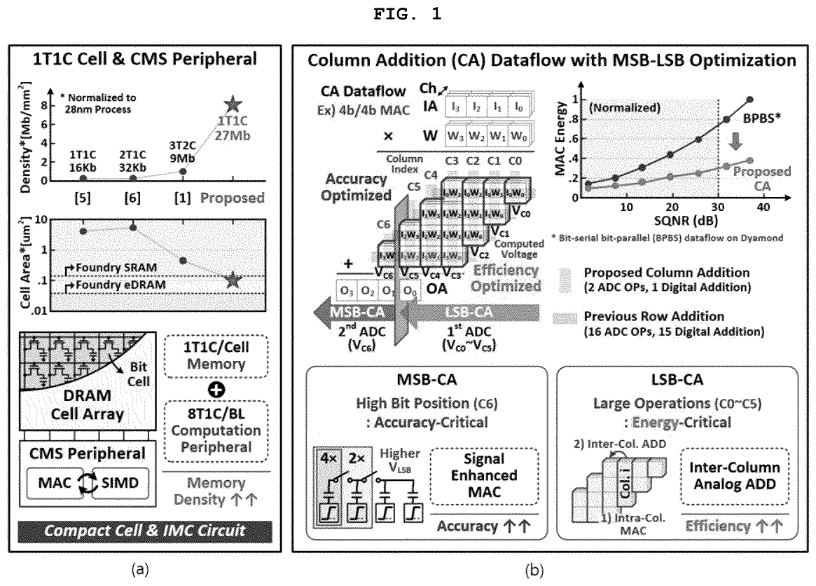

Prior thereto, a detailed description will be given of the need and overview of the IMC accelerator using the high-density operation circuit and the low-power sense amplifier as the peripheral circuit according to the present invention with reference to FIG. 1.

FIG. 1 is a diagram illustrating the need and overview of the IMC accelerator using the high-density operation circuit and the low-power sense amplifier as the peripheral circuit according to the present invention.

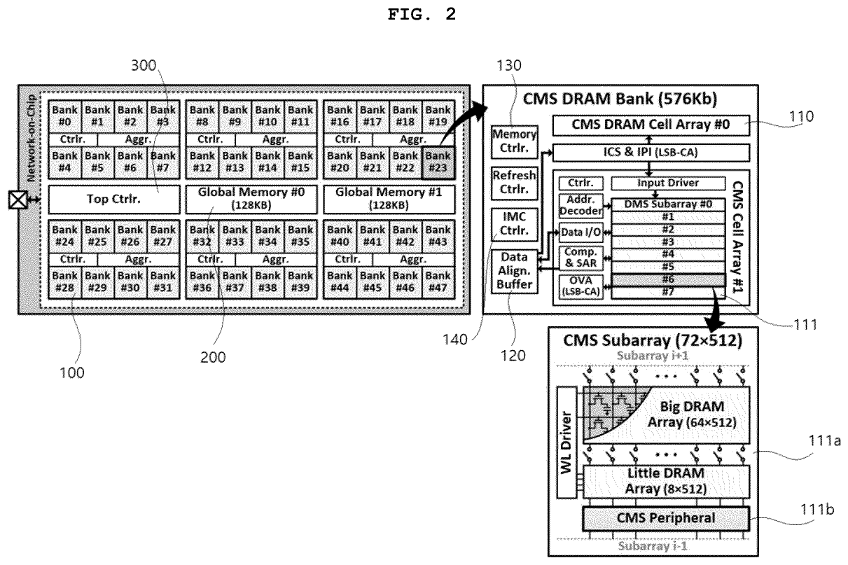

DRAM IMC increases memory density and improves system energy efficiency by reducing memory access as illustrated in FIG. 2A.

However, current DRAM IMC processors face two major challenges.

First, due to additional transistors and capacitors required for computation, the operation cell area thereof is 13 times the area of a DRAM cell and 36 times the area of an SRAM cell, which indicates limited memory density. Even in 1T1C IMC, a heavy processing logic and computation data path fail to utilize the high-density characteristics of DRAM cells.

Second, the existing bit-serial input dataflow IMC has limitations in achieving high energy efficiency while maintaining the SQNR (>30 dB) essential for advanced DNN models.

Since a multi-bit partial sum row is generated by multiplying by each input bit, several ADC operations and digital addition are repeatedly required for each single input bit.

The present invention proposes an energy-efficient and high-density 1T1C DRAM IMC accelerator.

As illustrated in FIG. 2B, each column (C0 to C6) requires different computational characteristics in terms of SQNR and energy consumption.

The designed column addition (CA) efficiently accumulates the dominant number of columns on the LSB (Least Significant Bit) side and accurately accumulates columns on the MSB (Most Significant Bit) side in the analog domain by deploying a programmable compact calculation logic.

The accelerator proposed in the present invention has three main features.

1) LSB Column Addition LSB-CA achieves high energy efficiency through analog column accumulation in compute lines CLs, reducing ADC work by 107 times.

2) LSB Column Addition MSB-CA achieves high SQNR and energy efficiency on each read by using a signal-enhanced (SE) MAC and a signal shifted (SS) ADC.

3) A switchable sense amplifier (SWSA) reduces read energy by 5.2 times for in-memory arithmetic SIMD.

FIG. 2 is a structural diagram of the IMC accelerator using the high-density operation circuit and the low-power sense amplifier as the peripheral circuit according to the present invention.

As illustrated in FIG. 2, the IMC accelerator using the high-density operation circuit and the low-power sense amplifier as the peripheral circuit according to the present invention includes 48 DRAM banks 100, a global SRAM 200, and a top-level controller 300 and has a total capacity of 27 Mb.

Each of the DRAM banks 100 includes a DRAM having a capacity of 576 kb and stores data as a memory or performs an operation in a memory.

The global SRAM 200 serves as an on-chip buffer that temporarily stores data when exchanging data with an off-chip memory.

The top-level controller 300 adjusts data movement between the off-chip memory and the DRAM bank 100, or between different DRAM banks 100, decodes an operation instruction, and transmits the decoded operation instruction to each DRAM bank 100.

The DRAM bank 100 includes two cell arrays 110, a data supply logic 120, a memory controller 130, and a controller 140 for IMC.

The cell array 110 includes a DRAM having a capacity of 288 kb as a memory having a smaller unit in the bank, and stores data as a memory or performs operations in the memory.

The data supply logic 120 serves as a buffer that sorts and stores input/output data of the cell array according to an operation type.

The memory controller 130 decodes a memory address and generates a control signal for read and write operations of the cell array.

The controller 140 for IMC further decodes an operation instruction received from the top-level controller and generates a control signal for operations in the memory.

The cell array 110 includes eight subarrays 111, and each of the subarrays 111 include a 72×512 1T1C DRAM array 111a having a big array (64×512) and a little array (8×512) separated by a BL switch, and an arithmetic circuit 111b.

The subarray 111 includes a DRAM having a capacity of 36 kb as a memory having a smaller unit in the cell array, and stores data as a memory or performs operations in the memory.

The big array (64×512) stores data as a memory having a large unit in the subarray.

The little array (8×512) is a memory having a small unit in the subarray, which stores general data similarly to the big array as a memory having a small unit, and particularly stores an intermediate operation result during SIMD operation.

As illustrated in FIGS. 1 and 2, the DRAM array 111a includes a memory cell having a 1T1C structure.

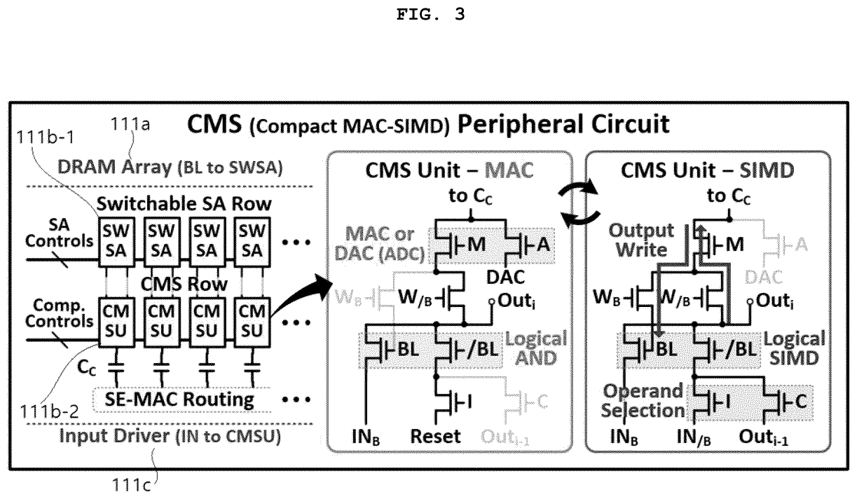

FIG. 3 is a diagram illustrating a structure of an 8T1C high-density operation circuit and operations of a MAC and an SIMD according to the present invention.

As illustrated in FIG. 3, the arithmetic circuit 111b includes a BL switch, one row of 512 8T switchable sense amplifiers (SWSA) 111b-1, and one row of 512 CMS units (Compact MAC-SIMD UNIT (CMSU)) 111b-2.

The arithmetic circuit 111b is adjacent to the sense amplifier 111b-1 and performs operations on data read from the DRAM array 111b and data input from the outside.

In particular, the arithmetic circuit 111b performs energy-efficient MAC operation and SIMD operation based on the high-density memory cell.

The sense amplifier 111b-1 is a dual mode sense amplifier which amplifies a BL voltage difference by being adjacent to the DRAM array 111a.

An input unit 111c inputs data to the DRAM array 111a.

The CMSU 111b-2 includes eight transistors and one capacitor, 8T1C, as illustrated in FIG. 3 to realize four multiplexers for selecting an input operand, logical operation on an operand, selecting whether to store output, and selecting MAC operation or ADC operation.

The capacitor selectively performs a MAC operation of a capacitance-coupled scheme and a DAC operation of a successive approximation register (SAR) ADC.

The multiplexer for selecting the input operand selects one operand from among inputs outside the memory array or outputs of an adjacent arithmetic circuit. The multiplexer for logical operation on the operand receives a selection signal from a BL and a BL bar to use the selection signal as an operand A, and receives two input signals as one of bits of an operand B, inverted bits of the operand B, GND, and VDD to perform 16 types of logical operations between the operands A and B.

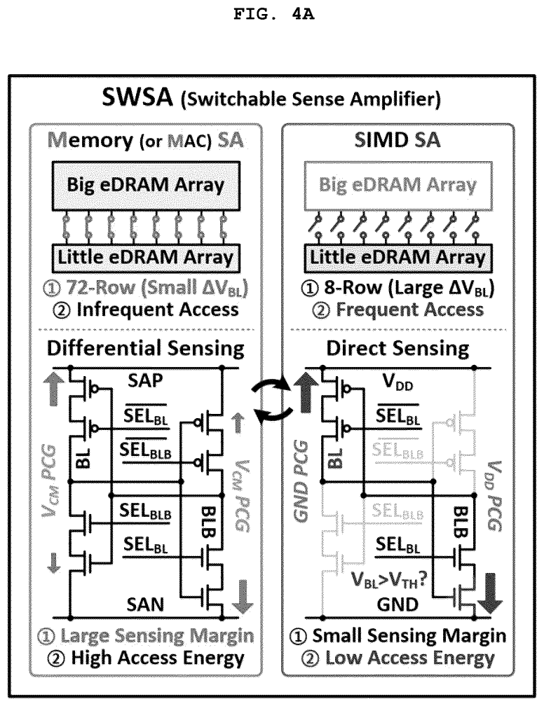

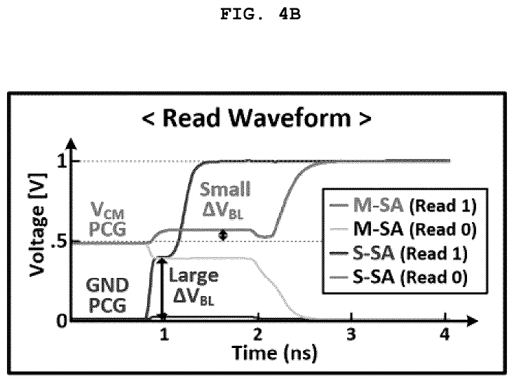

FIG. 4A is a diagram illustrating a structure of the big-little memory array and operations in a differential sense mode and a direct sense mode in the dual mode sense amplifier 111b-1 according to the present invention.

The dual mode sense amplifier 111b-1 includes four P-MOSFETs and four N-MOSFETs, and four additional transistors (TRs) are switched by /SELBL, /SELBLB, SELBLB, and SELBL.

The sense amplifier (SWSA) 111b-1 may be reconfigured in a differential sense mode (M-SA) for large sensing margin and a direct sense mode (S-SA) that deactivates both/SELBLB and SELBLB for low-power access.

The differential sense mode (M-SA) amplifies a small voltage difference through differential sensing and utilizes both BLs of the big array and the little array.

The direct sense mode (S-SA) maintains or inverts a BL voltage through direct sensing and consumes 52 times lower read energy than that of the differential sense mode (M-SA) by utilizing segmented BLs for only eight rows of the little array.

FIG. 4B is a diagram illustrating read operation waveforms in the differential sense mode and the direct sense mode of the sense amplifier (SWSA) 111b-1 according to the present invention.

In the case of the differential sense mode, the sense amplifier (SWSA) 111b-1 amplifies the BL and the BL bar to VDD and GND (or GND and VDD) according to data stored in a cell in which the BL and the BL bar are precharged to half a voltage of VDD and activated before a read operation.

Further, in the case of the direct sense mode, the sense amplifier (SWSA) 111b-1 precharges the BL and the BL bar connected to the activated cell to GND and precharges the rest to VDD, thereby maintaining GND when 0 is stored in the activated cell and amplifying the voltage to VDD when 1 is stored.

This structure enables high efficiency and precise data processing in the memory, and contributes to performance optimization, especially in low-power environments. The differential sense mode (M-SA) provides high detection precision, while the direct sense mode (S-SA) ensures effective data processing while significantly reducing energy consumption.

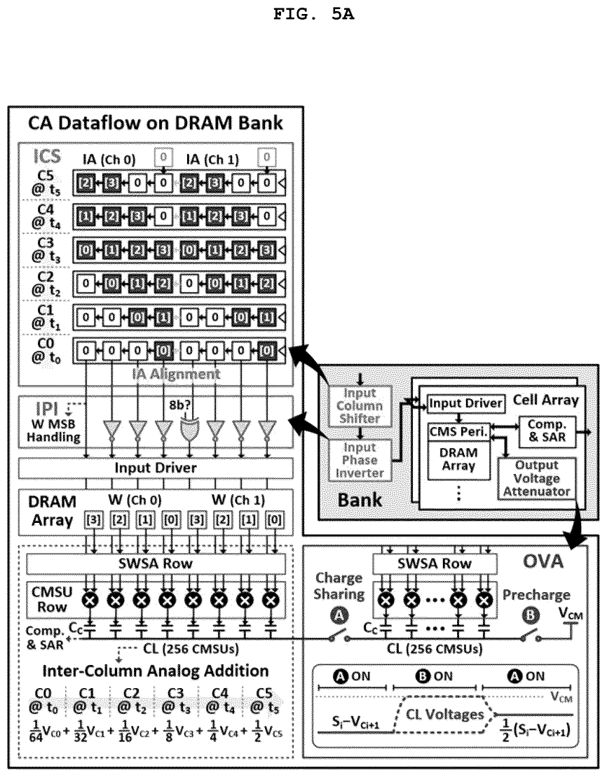

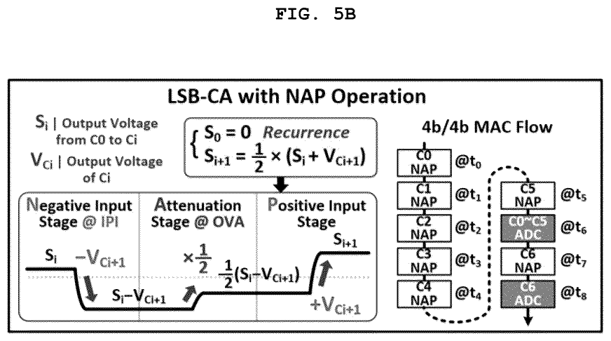

FIG. 5A is a diagram illustrating structures of an input column shifter ICS, an input phase inverter IPI, and an output voltage attenuator OVA for supporting a column addition data flow according to the present invention.

Along with this, FIG. 5B illustrates an operation of an analog column addition operation according to the present invention as a formula and a waveform.

The column addition data flow aims to optimally reduce ADC work for output accumulation through a negative attenuation positive (NAP) operation.

That is, the column addition data flow may perform an analog column addition operation using a capacitor coupling scheme and a signal weakening scheme in the analog voltage domain.

The NAP operation facilitates scaling of consecutive columns in the analog domain and adding the columns to previously accumulated results through three steps as illustrated in FIG. 5B.

First, in a negative input N step, a column value V_{Ci+1} is calculated and subtracted from an accumulated voltage Sᵢ. The input column shifter ICS matches input bits with associated weight positions of each column in a pipelined manner.

The sorted input is inverted in units of bits by the input phase inverter IPI and supplied to an input driver.

Next, the CMSU 111b-2 computes a column result using weights of the input driver and the subarray, and the result is accumulated on the compute line CL as a coupling voltage Sᵢ−V_{Ci}+1.

Second, in an attenuation A step, the compute line CL voltage accumulated for scale matching is reduced by half to (Sᵢ−V_{Ci}+1)/2 by the output voltage attenuator OVA. Finally, in a positive input P step, the input phase inverter IPI is reset to an initial voltage to add a column voltage to the compute line CL again.

In this way, desired (Sᵢ+V_{Ci}+1)/2 is generated. LSB-CA maintains an algorithmic upper limit of the SQNR by adjusting the number of analog accumulated columns. The proposed LSB-CA may reduce ADC operations by 53 times to 107 times due to the NAP operation.

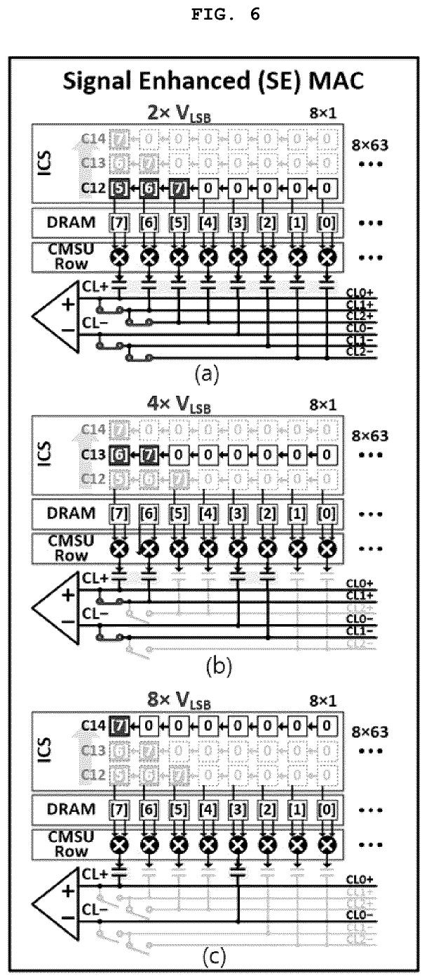

FIG. 6 is a diagram illustrating a structure and an operation of a signal enhancement operation capacitor array according to the present invention. The signal enhancement operation capacitor array improves the SQNR of the MSB column by adjusting a size of an effective coupling capacitor connected to a data flow CL, which is inversely proportional to a voltage level.

By isolating a redundant coupling capacitor of the data flow CL in a column having a corresponding position close to the MSB of output bits, a signal level of a column result may be amplified up to 8 times.

For example, in FIG. 6, when CMSU[7] is connected to CL0+ and CMSU[4] is connected to CL0− in a differential manner, the signal level may be amplified up to 8 times.

The signal enhancement operation capacitor array achieves a high SQNR without area overhead for an additional circuit.

That is, as illustrated in FIG. 6, the operation capacitor array has a differential capacitor array structure having a pair of operation lines (CL+ and CL−) for high-accuracy operation of the MAC operation, and has a separated capacitor array structure in which each operation line is separated into CL2+ and CL2− to which half of the entire capacitors are connected as illustrated in FIG. 6A, CL1+ and CL1− to which one quarter of the entire capacitors are connected as illustrated in FIG. 6B, and CL0+ and CL0− to which one quarter of the entire capacitors are connected as illustrated in FIG. 6C.

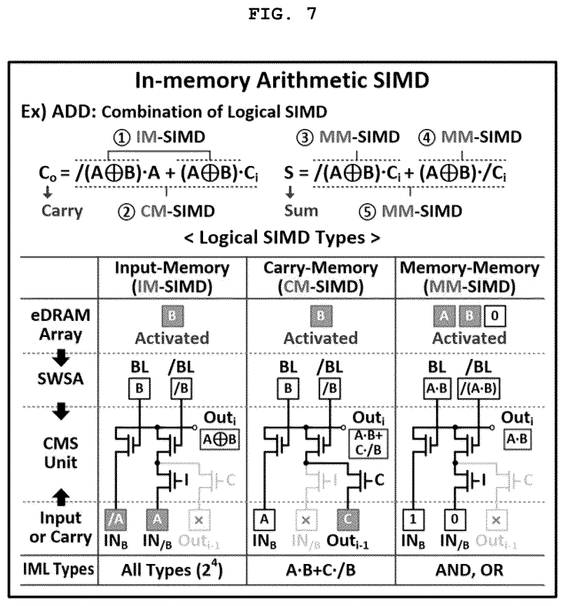

FIG. 7 illustrates a type and method of in-memory SIMD operation according to the present invention. The SIMD operation based on used operands is as follows.

Input-Memory (IM) computing is performed for 16 types of logical operations, Carry-Memory (CM) is performed for “IN.BL+C./BL”, and Memory-Memory (MM) is performed for “AND” and “OR”.

That is, the SIMD operation performs an arithmetic operation by combining repeated logical operations between two operands among input data outside the memory array, data read from the memory array, and output data of an adjacent arithmetic circuit.

A combination of these three types of logical operations realizes an arithmetic operation of the SIMD such as addition ADD. In this instance, using the direct sense mode of the dual mode sense amplifier 111b-1 reduces energy consumption of the arithmetic SIMD operation by 28 times.

The IMC accelerator using the high-density operation circuit and the low-power sense amplifier as the peripheral circuit according to the present invention has an effect of achieving memory density of 8.09 Mb/mm² and operation energy efficiency of 27.2 TOPS/W.

The dual mode sense amplifier and the big-little memory array of the IMC accelerator using the high-density operation circuit and the low-power sense amplifier as the peripheral circuit according to the present invention has an effect of maintaining a retention time of 278 us while reducing energy of the memory read operation by 5.2 times.

In addition, the IMC accelerator using the high-density operation circuit and the low-power sense amplifier as the peripheral circuit according to the present invention has an effect of reducing energy consumption of the in-memory SIMD operation using the dual mode sense amplifier by 3 times.

In addition, the column addition data flow and the analog column addition operation of the IMC accelerator using the high-density operation circuit and the low-power sense amplifier as the peripheral circuit according to the present invention has an effect of improving operation energy efficiency by about 3.3 times while improving the number of ADC operations by 10.7 times.

In addition, the signal enhancement operation capacitor array of the IMC accelerator using the high-density operation circuit and the low-power sense amplifier as the peripheral circuit according to the present invention has an effect of achieving an operational SQNR of 33.1 dB for a MAC operation between 8-bit operands.

In addition, the in-memory SIMD operation of the IMC accelerator using the high-density operation circuit and the low-power sense amplifier as the peripheral circuit according to the present invention has an effect of supporting a total of 16 logical operations and arithmetic operations through carry movement between logical operations, thereby diversifying functionality of in-memory operations.

Even though the technical idea of the present invention has been described above with reference to the attached drawings, this is merely an example of a preferred embodiment of the present invention and does not limit the present invention. In addition, it is a clear fact that anyone with ordinary knowledge in the technical field to which the present invention pertains may make various modifications and imitations within the scope of the technical idea of the present invention.

What is claimed is:

1. An in-memory computing (IMC) accelerator using a high-density operation circuit and a low-power sense amplifier as a peripheral circuit, the IMC accelerator comprising:
a plurality of dynamic random-access memory (DRAM) banks each including a pair of cell arrays, a data supply logic, a memory, and a controller for IMC, and including a DRAM having a predetermined capacity to store data as a memory or perform an in-memory operation;
a global SRAM configured to temporarily store data when exchanging data with an off-chip memory; and
a top-level controller configured to adjust data movement between the off-chip memory and the DRAM bank, or between different DRAM banks, decode an operation instruction, and transmit the decoded operation instruction to each DRAM bank, wherein:
the cell array includes a plurality of subarrays,
each of the subarrays includes a DRAM array including a big array and a little array, and an arithmetic circuit configured to perform an operation, and
the arithmetic circuit includes:
a sense amplifier configured to amplify a bit line voltage difference; and
a compact multiply-accumulate (MAC)-single instruction multiple data (SIMD) unit (CMSU) for an MAC operation and an SIMD operation.

2. The IMC accelerator according to claim 1, wherein the arithmetic circuit has an 8T1C circuit structure having a multiplexer to which a transistor and an operation capacitor are connected to select an input operand, perform a logical operation on an operand, select whether to store output, and select an MAC operation or an analog-to-digital converter (ADC) operation.

3. The IMC accelerator according to claim 2, wherein the capacitor performs both a MAC operation of a capacitance-coupled scheme and a DAC operation of a successive approximation register (SAR) ADC.

4. The IMC accelerator according to claim 2, wherein the multiplexer selects one operand from among input outside a memory array or output of an adjacent arithmetic circuit to select the input operand.

5. The IMC accelerator according to claim 2, wherein, for a logical operation on the operand, the multiplexer receives a selection signal from a bit line and a bit line bar to use the selection signal as an operand A, and receives two input signals as one of bits of an operand B, inverted bits of the operand B, GND, and VDD to perform 16 types of logical operations between the operands A and B.

6. The IMC accelerator according to claim 2, wherein the multiplexer stores output bits of the multiplexer for the logical operation on the operand in the capacitor to select whether to store the output, then shares a charge on the bit line, and operates the sense amplifier to perform a memory write operation.

7. The IMC accelerator according to claim 1, wherein the sense amplifier comprises:
an N-MOSFET and a P-MOSFET for voltage difference amplification of a bit line and a bit line bar; and
an additional N-MOSFET and an additional P-MOSFET for selection of the bit line or the bit line bar.

8. The IMC accelerator according to claim 7, wherein the sense amplifier is reconfigurable to selectively operate in either a differential sense mode or a direct sense mode.

9. The IMC accelerator according to claim 8, wherein, in the differential sense mode, two N-MOSFETs and two P-MOSFETs for selecting the bit line or the bit line bar of the sense amplifier are both turned on to amplify the bit line voltage difference.

10. The IMC accelerator according to claim 8, wherein, in the direct sense mode, when data of a cell connected to the bit line or the bit line bar is read, one N-MOSFET and one P-MOSFET for selection of the bit line or the bit line bar are exclusively turned on, so that a voltage difference is amplified based on whether a voltage of the bit line or the bit line bar exceeds a threshold voltage of the N-MOSFET for amplification of the voltage difference.

11. The IMC accelerator according to claim 1, wherein the DRAM array comprises:
a big array including 64 memory rows;
a little array including 8 memory rows; and
a bit line switch configured to separate the big array and the little array.

12. The IMC accelerator according to claim 1, wherein the MAC operation has a column addition data flow configured to sequentially accumulate MAC operation results of input data and weight data from a least significant bit (LSB) position to a most significant bit (MSB) position.

13. The IMC accelerator according to claim 12, wherein the column addition data flow is allowed to perform an analog column addition operation using a capacitor coupling scheme and a signal weakening scheme in an analog voltage domain.

14. The IMC accelerator according to claim 1, wherein the MAC operation has, as a differential capacitor array structure having a pair of operation lines (CL+ and CL−), a separated capacitor array structure in which each operation line is separated into CL0+ and CL0− to which one quarter of entire capacitors are connected, CL1+ and CL1− to which one quarter of the entire capacitors are connected, and CL2+ and CL2− to which half of the entire capacitors are connected.

15. The IMC accelerator according to claim 1, wherein the SIMD operation performs an arithmetic operation by combining repeated logical operations between two operands among input data outside a memory array, data read from the memory array, and output data of an adjacent arithmetic circuit.
